(19) United States
(12) Patent Application Publication
(10) Pub. No.: US 2008/0061838 A1
(43) Pub. Date: Mar. 13, 2008

(54) Differential-type high-speed phase detector

(76) Inventors: Jinn-Shyan Wang, Ming-Hsiung (TW); Yi-Ming Wang, Ming-Hsiung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/518,452

(22) Filed: Sep. 11, 2006

(51) Int. Cl. H03D 13/00

(52) U.S. Cl. 327/3

(57) ABSTRACT

A differential-type high-speed phase detector is provided, and it includes a first DTHT module and a second DTHT module wherein these two DTHT modules are the same. The first DTHT module includes a first input for receiving a signal CK_ref, a second input for receiving a signal CK_fb, a first logic unit, a second logic unit, a third logic unit and an output. An imperceptible delay period difference is produced by the difference of the capacitance value between two capacitors to diminish the size of the dead zone of the phase detector in accordance with the prior art. As a result, the differential-type high-speed phase detector also keeps high speed and tri-state outputs such that the performance of the dead zone is enhanced.

### BACKGROUND

1. Field of Invention

The present invention relates to a phase detector, and more particularly to a differential-type high-speed phase detector.

2. Description of Related Art

The phase detector is generally used to improve relative control loops wherein the clock signal is skewed, such as the delay-locked loop (DLL), phase-locked loop (PLL) and clock/date recovery circuit. The circuit performances of the phase detectors and the loop controllers of these kinds of loops directly affect the phase error convergence result of the entire loop. The reaction speed of the phase detector affects the highest working frequency of the loops, and the minimal phase difference of the phase detector affects the phase error resolution of the loops. The minimal phase difference is called the dead zone of the phase detector, and the smaller dead zone causes the higher resolution. Therefore, creating a phase detector with high-speed and higher resolution is the research purpose of the designers.

Reference is made to FIG. 1 and FIG. 2, wherein FIG. 1 is a circuit block diagram illustrating a phase detector 100 with high speed, and high resolution in accordance with the prior art and FIG. 2 illustrates a circuit diagram of the half-transparent (HT) module of the phase detector in FIG. 1.

The phase detector 100 includes a first half-transparent (HT) module 110 and a second half-transparent (HT) module 120. The first half-transparent (HT) module 110 includes a first input 111 (y) for receiving a signal CK_ref, a second input 112 (x) for receiving a signal CK_fb and an output 113 ( o̅u̅t̅_̅u̅). The second half-transparent (HT) module 120 includes a first input 121 (y) for receiving a signal CK_ref, a second input 122 (x) for receiving a signal CK_fb and an output 123 ( o̅u̅t̅_̅d̅). The first input 111 (y) of the first half-transparent (HT) module 110 connects with the second input 122 (x) of the second half-transparent (HT) module 120. The first input 121 (y) of the second half-transparent (HT) module 120 connects with the second input 112 (x) of the first half-transparent (HT) module 110. Because the circuit schemes of the first half-transparent (HT) module 110 and the second half-transparent (HT) module 120 are the same, only the first half-transparent (HT) module 110 is taken as an example in the following.

Reference is made to FIG. 2, the first HT module 110 includes a first logic unit 130 and a second logic unit 140.

The first logic unit 130 includes a first switch element 131 (M₀, P-type metal-oxide-semiconductor: PMOS), a second switch element 132 (M₁, P-type metal-oxide-semiconductor: PMOS) and a third switch element 133 (M₂, N-type metal-oxide-semiconductor: NMOS), wherein these three switch elements are cascaded with each other. A drain (D) of the second switch element 132 connects with a drain (D) of the third switch element 133 to form an output 134 (w) of the first logic unit 130.

The second logic unit 140 includes a first switch element 141 (M₃, P-type metal-oxide-semiconductor: PMOS), a second switch element 142 (M₄, N-type metal-oxide-semiconductor: NMOS) and a third switch element 143 (M₅, N-type metal-oxide-semiconductor: NMOS), wherein these three switch elements are cascaded with each other. The first switch element 141 and the second switch element 142 of the second logic unit 140 respectively have a drain (D) connected to each other to form an output 144 of the second logic unit 140. Besides, z̅ denotes the output 144 of the second logic unit 140 that is connected with the output 113 of the first HT module 110.

Refer to FIG. 3 and FIG. 4. FIG. 3 illustrates a first timing diagram of the phase detector in accordance with the prior art, and FIG. 4 illustrates a second timing diagram of the phase detector in accordance with the prior art. In FIG. 3, the rising edge of the input signal y is lagged than the rising edge of the input signal x. In FIG. 4, the rising edge of the input signal y is led to the rising edge of the input signal x.

Reference is made to FIG. 2 and FIG. 3, taking the first timing diagram as an example. When the input signal y and the input signal x are both low level (y=0, x=0), the first switch element 131 (M₀) and the second switch element 132 (M₁) of the first logic unit 130 are closed_such that the signal w is raised to a high level. Thus, the first switch element 141 (M₃) of the second logic unit 140 is opened and the third switch element 143 (M₅) of the second logic unit 140 is closed. Meanwhile, the second switch element 142 (M₄) of the second logic unit 140 is opened because the input signal x is low level. Therefore, the output signal z̅ of the first HT module 110 is kept in the previous condition (assumed high level). When the input signal x begins to go to a high level, the second switch element 132 (M₁) of the first logic unit 130 is opened, and the second switch element 142 (M₄) of the second logic unit 140 is closed. Therefore, the output signal z̅ of the first HT module 110 goes to a low level from an original high level. The output signal w of the first logic unit 130 goes to a low level when the input signal y goes to a high level. In this way, the first switch element 141 (M₃) of the second logic unit 140 is closed and the third switch element 143 (M₅) is opened to raise the output signal z̅ to a high level. So, the output signal z̅ is kept at a low level until the input signal y goes to a high level. As a result, the period during the output signal z̅ is at a low level is called the phase difference of the rising edges of the input signal y and the input signal x in the first timing diagram wherein the rising edge of the input signal y is lagged behind the rising edge of the input signal x.

Reference is made to FIG. 2 and FIG. 4, and based on the theory in the previous description. The output signal z̅ of the first HT module 110 is kept at a high level because there is no discharge path in the second timing diagram wherein the rising edge of the input signal y is led to the rising edge of the input signal x.

Consequently, when the positive edges (phase difference) of the input signal y and the input signal x are close to each other, the phase difference is smaller. In this situation, the pulse period is shorter where the output signal z̅ is at a low level. When the output signal z̅ is at a low level, a linear relation between the pulse period of the output signal z̅ and the phase difference of the input signal y and the input signal x cannot not be accurately maintained during practical circuit operation. The output of the circuit is affected by the reaction period of the MOS switch elements, the raising period of the input signal y and the input signal x, the falling period of the input signal y and the input signal x and so on. As a result, when the phase difference between the input signal y and the input signal x is significantly small (generally, it is more than ten pico-second), the phase difference between a minimal input signal y and input signal x for generating an integrated output signal z̅ is called a size of the dead zone of the phase detector 100.

Reference is made to FIG. 5, which illustrates a curve chart of the input-output conversion of the phase detector in accordance with the prior art. Although there is a linear relation in this curve chart of the input-output conversion, the symmetrical point is not the origin of the coordinate (the central point of the coordinate). Moreover, the minimal value of the dead zone in size of this phase detector is about 40 pico-second (ps).

Refer to FIG. 6. FIG. 6 illustrates a circuit diagram of another high speed phase detector 200 based on dynamic circuit design, and the phase detector 200 has an excellent dead zone size and operating performance. The detector 200 includes a first dynamic circuit module 210, a second dynamic circuit module 220 and a RS latch 230. The RS latch 230 comprises multiple NOR logic gates arranged in a two-stage manner. The first dynamic circuit module 210 includes a PMOS switch element M₀ and two NMOS switch elements, M₁ and M₂, wherein these three switch elements are cascaded with each other. The second dynamic circuit module 220 includes a PMOS switch element M₃ and two NMOS switch elements, M₄ and M₅, wherein these three switch elements are cascaded with each other. The gates (G) of the switch elements M₀, M₂, M₃ and M₅ connect with the precharge input signal (CK_precharge). The gate (G) of the switch element M₁ connects with the input signal CK_ref, and the gate (G) of the switch element M₄ connects with the input signal CK_fb. The RS latch 230 consists of multiple NOR logic gates arranged in a two-stage manner that latch the output signal A from the dynamic circuit module 210 and the output signal B from the dynamic circuit module 220.

Although this phase detector 200 using the dynamic circuit can greatly reduce the circuit complexity and has excellent efficiency in the dead zone (less than 10 ps value of the dead zone in this phase detector 200 under 1 Ghz operation speed), the dynamic circuit of this phase detector 200 needs an additional input signal CK_precharge to precharge the dynamic circuits. Thus, handling the control timing of this circuit is difficult such that applying directly this kind of circuit to other circuit designs is also difficult.

### SUMMARY

It is therefore an objective of the present invention to provide a differential-type high-speed phase detector to solve the dead zone performance problem of the high-speed phase detector in accordance with the prior art that is restrained by the reaction speed of the element.

It is another objective of the present invention to provide a differential-type high-speed phase detector to solve the circuit timing control problem of another high-speed phase detector in accordance with the prior art that is difficult to handle because of the need of an additional input signal CK_precharge such that this kind of circuit is also difficult to be applied to other circuit designs.

A differential-type high-speed phase detector is provided. This phase detector includes a first DTHT (differential-type half-transparent) module and a second DTHT module. The first DTHT module includes a first input for receiving a signal CK_ref, a second input for receiving a signal CK_fb, a first logic unit, a second logic unit, a third logic unit and an output. The second DTHT module includes a first input for receiving a signal CK_ref, a second input for receiving a signal CK_fb and an output. Furthermore, the first input of the first DTHT module connects with the second input of the second DTHT module, and the second input of the first DTHT module connects with the first input of the second DTHT module. The output of the first DTHT module connects with an output o̅u̅t̅_̅u̅, and the output of the second DTHT module connects with an output o̅u̅t̅_̅d̅.

The phase detector utilizes to set the capacitance value of a second capacitor being less than the capacitance value of a first capacitor in the first logic unit to generate an imperceptible delay period difference caused by the differential effect of the capacitance value between two capacitors. Therefore, the imperceptible delay period difference of the differential-type high-speed phase detector can diminish the size of the dead zone of the phase detector in accordance with the prior art, and also keeps high speed and tri-state output.

Compared to another high-speed phase detector in accordance with the prior art, the additional input signal CK_precharge is not needed in the present invention to simplify the design.

Preferably, the phase detector further includes a fourth logic unit having a first logic gate (buffer) and a second logic gate (buffer), wherein the first logic gate is cascaded between the input signal CK_ref (y) and the first logic unit, and the second logic gate is cascaded between the input signal CK_fb (x) and the first logic unit.

Preferably, these two buffers are set on the paths of the input signal y and the input signal x to not only reduce signal strength tolerance of the input signal y and the input signal x to assure the signal slope but also accelerate the rising/falling period of the signal to obtain enhanced performance.

As embodied and broadly described herein, the differential-type high-speed phase detector of the present invention provides many advantages:

1. In the differential-type high-speed phase detector of the present invention, an imperceptible delay period difference is generated to diminish the dead zone of the phase detector in accordance with the prior art, and an enhanced performance of the dead zone is provided.

2. In the differential-type high-speed phase detector of the present invention, only the input signal y and the input signal x are used to operate without an additional input signal to simplify the circuit timing control for applying this circuit to other designs.

3. In the differential-type high-speed phase detector of the present invention, two buffers are set on the paths of the input signal y and the input signal x to not only reduce signal strength tolerance of the input signal y and the input signal x to assure the signal slope but also accelerate the rising/falling period of the signal to obtain enhanced performance.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a circuit block diagram which illustrates a phase detector with high speed and higher resolution in accordance with the prior art;

FIG. 2 illustrates a circuit diagram of the half-transparent (HT) module of the phase detector in FIG. 1;

FIG. 3 illustrates a first timing diagram of the first working condition of the phase detector in accordance with the prior art;

FIG. 4 illustrates a second timing diagram of the second working condition of the phase detector in accordance with the prior art;

FIG. 5 illustrates a curve chart of the input-output conversion of the phase detector in accordance with the prior art;

FIG. 6 is a circuit diagram which illustrates another phase detector based on dynamic circuit design in accordance with the prior art;

FIG. 7 is a circuit block diagram which illustrates a differential high-speed phase detector of the first embodiment of the present invention;

FIG. 8 is a circuit diagram which illustrates a DTHT module of the first embodiment in FIG. 7;

FIG. 9 illustrates a timing diagram of the first working condition of the differential high-speed phase detector of the present invention;

FIG. 10 illustrates a timing diagram of the second working condition of the differential high-speed phase detector of the present invention;

FIG. 11 illustrates a curve chart of the input-output conversion of the differential high-speed phase detector of the present invention;

FIG. 12 illustrates another curve chart of the input-output conversion of the differential high-speed phase detector of the present invention; and

FIG. 13 is another circuit diagram which illustrates a second embodiment of the DTHT module in FIG. 7.

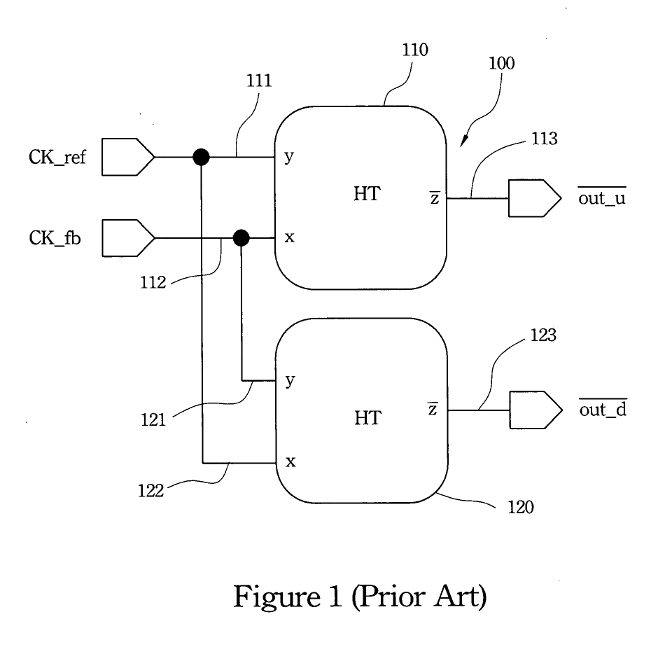

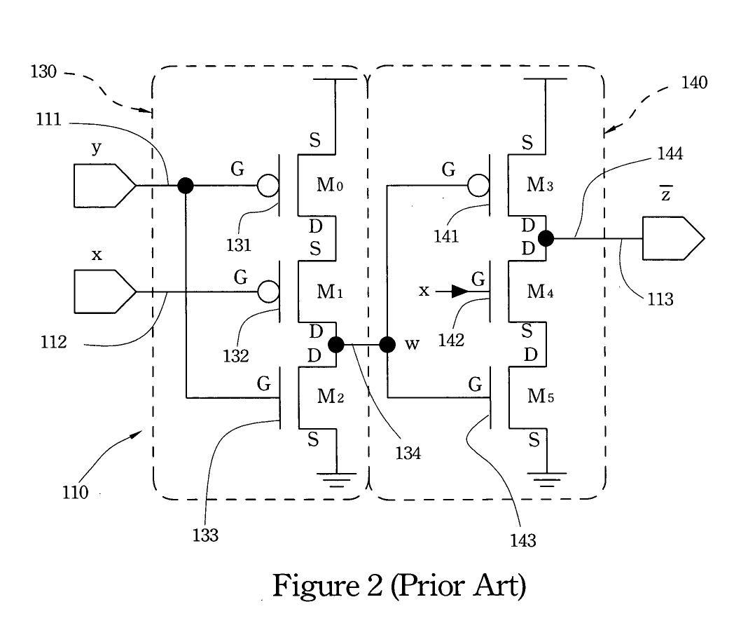

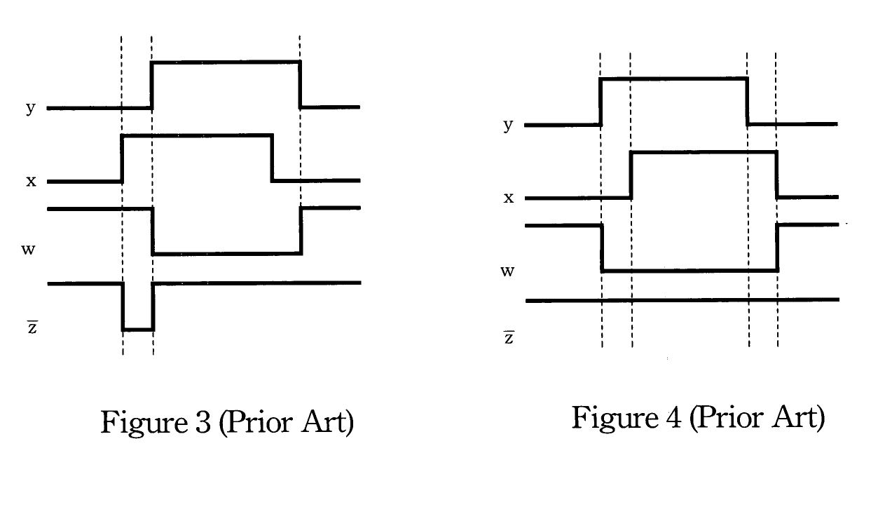

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

While the specification concludes with claims defining the features of the invention that are regarded as novel, it is believed that the invention will be better understood from a consideration of the following description in conjunction with the figures, in which like reference numerals are carried forward.

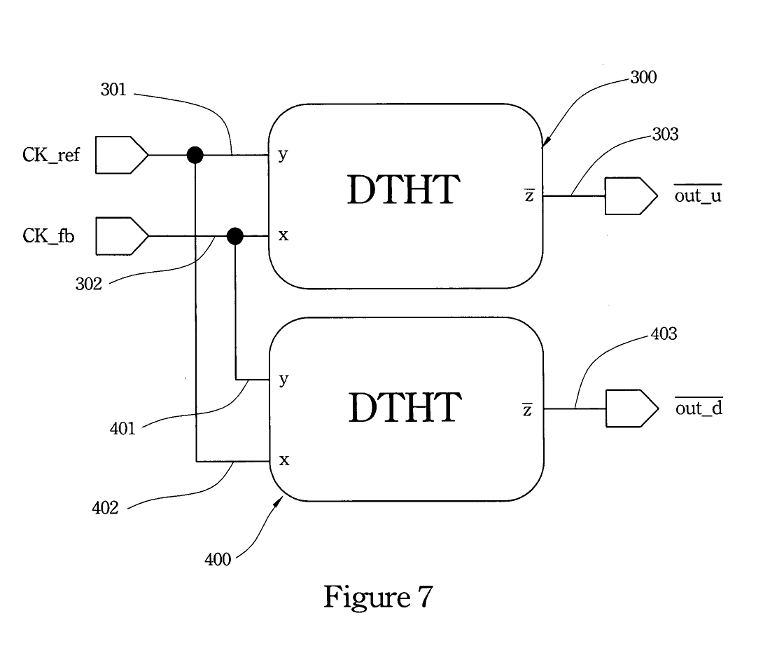

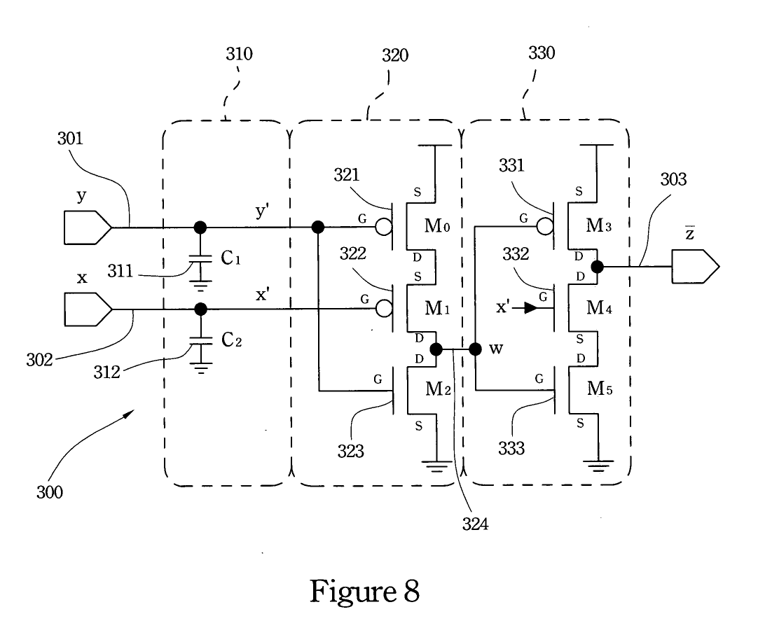

Refer to FIG. 7 and FIG. 8. FIG. 7 illustrates a circuit block diagram of the differential high-speed phase detector of the first embodiment of the present invention, and FIG. 8 illustrates a circuit diagram of a DTHT module of the first embodiment in FIG. 7.

The differential-type high-speed phase detector of the first embodiment of the present invention includes a first DTHT module 300 and a second DTHT module 400. Because the circuit scheme of the first DTHT module 300 is the same as the circuit scheme of the second DTHT module 400, only the first DTHT module 300 is described in the following.

The first DTHT module 300 includes a first input 301 for receiving a signal CK_ref, a second input 302 for receiving a signal CK_fb, a first logic unit 310, a second logic unit 320, a third logic unit 330 and an output 303.

The second DTHT module 400 includes a first input 401 for receiving a signal CK_ref, a second input 402 for receiving a signal CK_fb and an output 403. Furthermore, the first input 301 of the first DTHT module 300 connects with the second input 402 of the second DTHT module 400, and the second input 302 of the first DTHT module 300 connects with the first input 401 of the second DTHT module 400. The output 303 of the first DTHT module 300 connects with an output o̅u̅t̅_̅u̅, and the output 403 of the second DTHT module 400 connects with an output o̅u̅t̅_̅d̅.

The first logic unit 310 includes a first capacitor 311 (C1) and a second capacitor 312 (C2). The capacitors 311 and 312 may use fixed capacitors or metal-oxide-semiconductor (MOS) capacitors. The capacitance value of the first capacitor 311 is slightly bigger than the capacitance value of the second capacitor 312.

The input signal y entered from the first input 301 is transformed to a first input new signal y′ through the first capacitor 311 (C1); the input signal x entered from the second input 302 is transformed to a second input new signal x′ through the second capacitor 312 (C2).

The second logic unit 320 includes a first switch element 321 (M₀, P-type metal-oxide-semiconductor: PMOS), a second switch element 322 (M₁, P-type metal-oxide-semiconductor: PMOS) and a third switch element 323 (M₂, N-type metal-oxide-semiconductor: NMOS), wherein these three switch elements are cascaded with each other. Both the gates (G) of the first switch element 321 and the third switch element 323 are connected with the first input 301 of the first DTHT module 300, and the gate (G) of the second switch element 322 is connected with the second input 302 of the first DTHT module 300. The second switch element 322 and the third switch element 323 of the second logic unit 320 respectively have a drain (D) connected to each other to form an output 324 (w) of the second logic unit 320.

The third logic unit 330 includes a first switch element 331 (M₃, P-type metal-oxide-semiconductor: PMOS), a second switch element 332 (M₄, N-type metal-oxide-semiconductor: NMOS) and a third switch element 333 (M₅, N-type metal-oxide-semiconductor: NMOS), wherein these three switch elements are cascaded with each other. Both the gates (G) of the first switch element 331 and the third switch element 333 are connected with the output 324 (w) of the second logic unit 320, and a gate (G) of the second switch element 332 is connected with the second input new signal x′. The first switch element 331 and the second switch element 332 of the third logic unit 330 respectively have a drain (D) connected to each other to form an output 303 (z) of the first DTHT module 300.

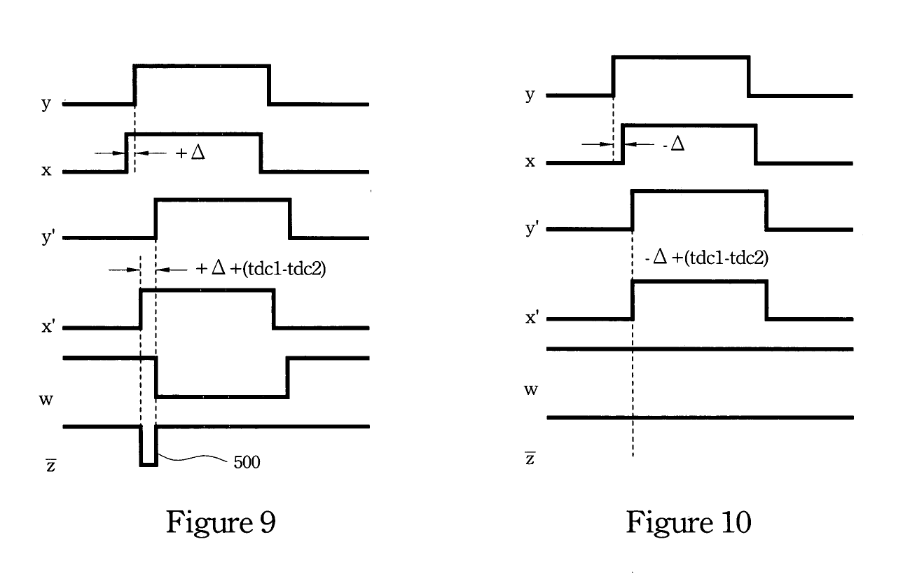

Refer to FIG. 8. The first capacitor 311 and the second capacitor 312 are set on the paths of the input signal x and the input signal y in parallel. Moreover, the capacitance value of the first capacitor 311 is slightly bigger than the capacitance value of the second capacitor 312. Therefore, an imperceptible delay period difference tdc1−tdc2 is produced on the paths connected with the input signal y and the input signal x (shown in FIG. 9).

Refer to FIG. 9 and FIG. 10. FIG. 9 illustrates a timing diagram of the first working condition, and FIG. 10 illustrates a timing diagram of the second working condition of the differential-type high-speed phase detector of the present invention. In FIG. 9, the rising edge of the input signal y is lagged than the rising edge of the input signal x. In FIG. 10, the rising edge of the input signal y is led to the rising edge of the input signal x.

Refer to FIG. 8 and FIG. 9. In the first logic unit 310, the period difference+Δ (the phase difference is +Δ/t_{cyc}·2π, and t_{cyc} denotes the periods of the input signals x and y) between the input signal x and the input signal y is transformed to the period difference+Δ+(tdc1−tdc2) between the first input new signal y′ and the second input new signal x′. As the aforementioned description, the imperceptible delay period difference tdc1−tdc2 is produced by the capacitance difference between the first capacitor 311 and the second capacitor 312 of the first logic unit 310. In the second logic unit 320, when the first input new signal y′ and the second input new signal x′ are both low level (y′=0, x′=0), the first switch element 321 (M₀) and the second switch element 322 (M₁) are closed. Therefore, the output signal w is raised to a high level such that the first switch element 331 (M₃) of the third logic unit 330 is opened and the third switch element 333 (M₅) is closed. Meanwhile, because the second input new signal x′ is at a low level, the second switch element 332 (M₄) of the third logic unit 330 is opened to keep the output signal z̅ in the previous high level condition. When the second input new signal x′ is transformed to a high level, the second switch element 322 (M₁) of the second logic unit 320 is opened, and the second switch element 332 (M₄) of the third logic unit 330 is closed to transform the output signal z̅ from high level to low level. The output signal z̅ is kept at a low level until the first input new signal y′ is transformed to a high level. The output signal (w) of the second logic unit 320 is transformed to a low level because the first input new signal y′ is transformed to a high level. Thus, the first switch element 331 (M₃) of the third logic unit 330 is closed and the third switch element 333 (M₅) is opened to raise the output signal z̅ to a high level. As a result, the output signal z̅ is kept in low level until the first input new signal y′ is transformed to a high level.

Consequently, the rising edge signal period difference (+Δ+(tdc1−tdc2)) between the second input new signal x′ and the first input new signal y′ is bigger than the period difference (+Δ) between the input signal x and the input signal y because of the differential effect of the capacitance value between the capacitor C1 and the capacitor C2 of the first logic unit 310. Thus, each of the above switch elements (M₀˜M₅) has a longer period to generate a complete signal with an accurate level to output.

In the timing diagram of the first embodiment in FIG. 9 which illustrates capacitance difference effect of the first logic unit 310. If the period difference +A between the original input signals x and y is unable to let the output signal z̅ be completely discharged to a low level to generate a complete signal output with an accurate level through the path caused by the closing of the second switch element 332 (M₄) and the third switch element 333 (M₅), the sum (+Δ+(tdc1−tdc2)) of the imperceptible delay period difference (tdc1−tdc2) caused by the capacitance differential effect and the original period difference +Δ of the first logic unit 310 allows each of the above switch elements (M0˜M5) to have a sufficient period to generate a complete signal output at an accurate level.

Likewise, if the phase difference (−Δ) between the rising edge of the input signal y and the rising edge of the input signal x is dealt by the capacitance differential effect of the first logic unit 310, a period difference −Δ+(tdc1−tdc2) between the first input new signal y′ and the second input new signal x′ is generated. Besides, in order to insulate the discharge path of the input signal z̅ of the DTHT module and keep the signal at in a high level, the value of (tdc1−tdc2) is set lower than or same as the Δ value. Thus, in the assumed condition, (tdc1−tdc2)=Δ, the equivalent period difference value in the first embodiment in FIG. 9 is shown as the following equation:

+Δ+(tdc1−tdc2)=2Δ

; and another equivalent period difference value in the second embodiment in FIG. 10 is shown as the following equation:

−Δ+(tdc1−tdc2)=0

When the first DTHT module 300 is dealt with the capacitance difference effect of the first logic unit 310, and conditions of generating the imperceptible delay period difference (tdc1−tdc2) and the period difference A are the same, a complete logic level output pulse 500 with a 2Δ(+Δ+(tdc1−tdc2) width is generated in the first working condition timing diagram of FIG. 9. The output signal z̅ is maintained at a high level because there is no discharge path in the second working condition timing diagram of FIG. 10. The differential-type high-speed phase detector of the present invention not only diminishes the size of the dead zone of the phase detector in accordance with the prior art but also keeps original tri-state output [( o̅u̅t̅_̅u̅, o̅u̅t̅_̅d̅)=(0,1)(1,0)(1,1,)].

Considering manufacturing inaccuracies, the produced (tdc1−tdc2) value is possibly bigger than the Δ value. In this condition, the original output ( o̅u̅t̅_̅u̅, o̅u̅t̅_̅d̅)=(0,1,)(1,0)(1,1) is transformed to the output ( o̅u̅t̅_̅u̅, o̅u̅t̅_̅d̅)=(0,1)(1,0)(0,0,). In other words, when the phase difference between the input signal y and the input signal x is approximately zero, both the output o̅u̅t̅_̅u̅ and the output o̅u̅t̅_̅d̅ each generate a low level pulse signal (500) with different pulse widths. Therefore, the result of phase lagging or leading between the two input signals can be determined by the width of two output pulse signals.

The tri-state output result caused when the manufacturing process inaccuracies occur or dead zone is approximately zero does not affect the application using a charge pump to be the circuit controller. Even though each of the output o̅u̅t̅_̅u̅ and the output o̅u̅t̅_̅d̅ generate a pulse signal, the charge pump (not shown) of the phase detector can determine the current control level depending on the difference of the pulse width.

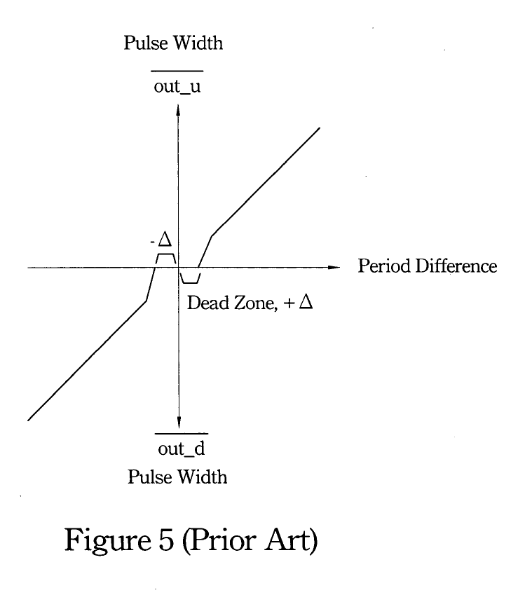

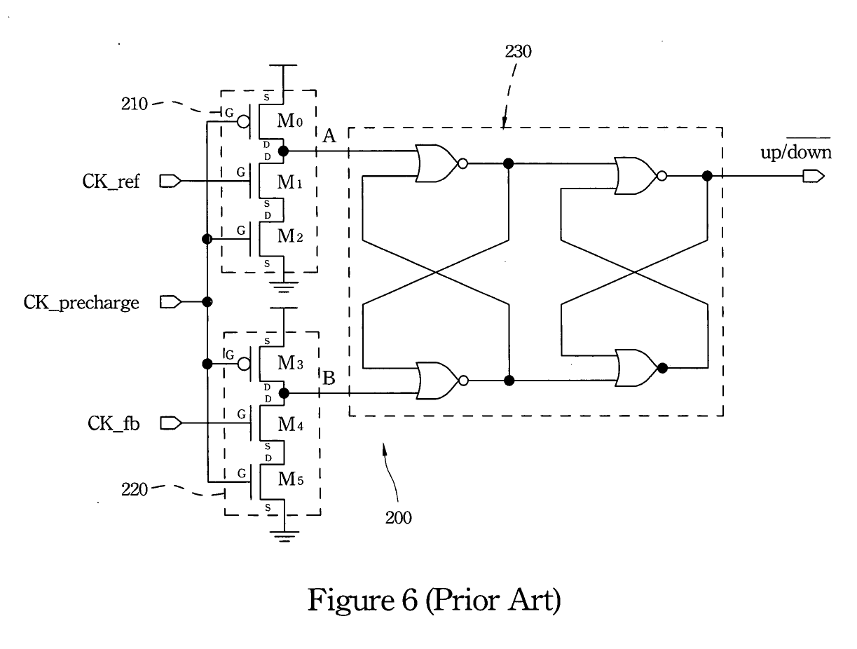

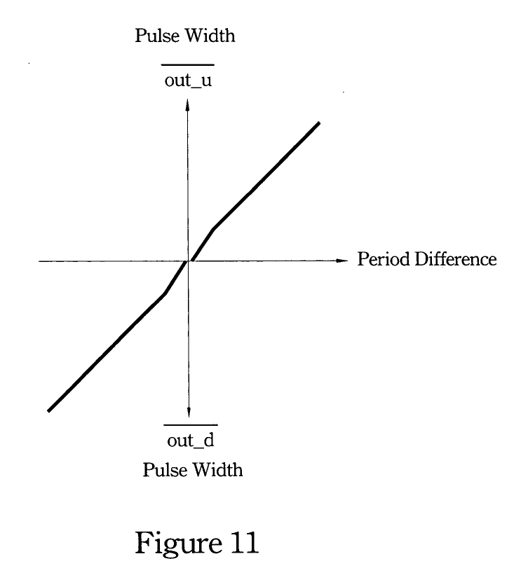

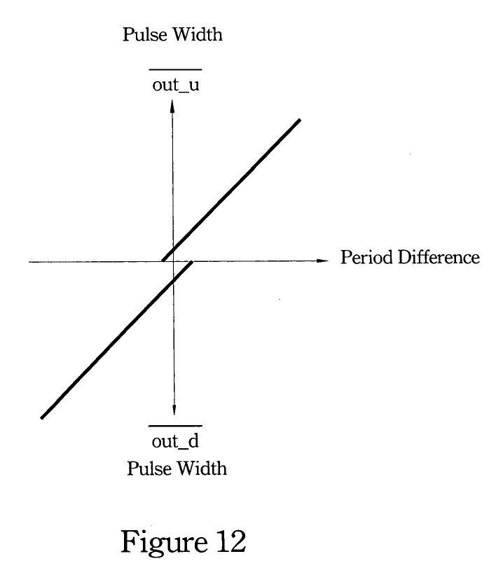

Refer to FIG. 5, FIG. 11 and FIG. 12. FIG. 11 illustrates a curve chart of the input-output conversion of the differential high-speed phase detector of the present invention, and FIG. 12 illustrates another curve chart of the input-output conversion of the differential high-speed phase detector of the present invention. The size of the dead zone of the phase detector of the present invention is much smaller than the one of the prior art such that the dead zone efficiency of the present invention is much better.

Compared with the defects of the phase detector in accordance with the prior art, the differential-type high-speed phase detector of the present invention modifies the capacitance value of the different path to generate an imperceptible delay period difference to increase the period difference between the input signal y and the input signal x of the two DTHT modules. Thus, the switch elements (M₀-M₅) have a sufficient switch period to respond and the output signal z̅ is completely discharged to low level. The DTHT module of this invention can diminish the size of the dead zone of the HT module of the phase detector in accordance with the prior art. Moreover, only the input signal y and the input signal x are used without an additional input signal. As a result, the easier timing control of the circuit can be directly applied to other designs.

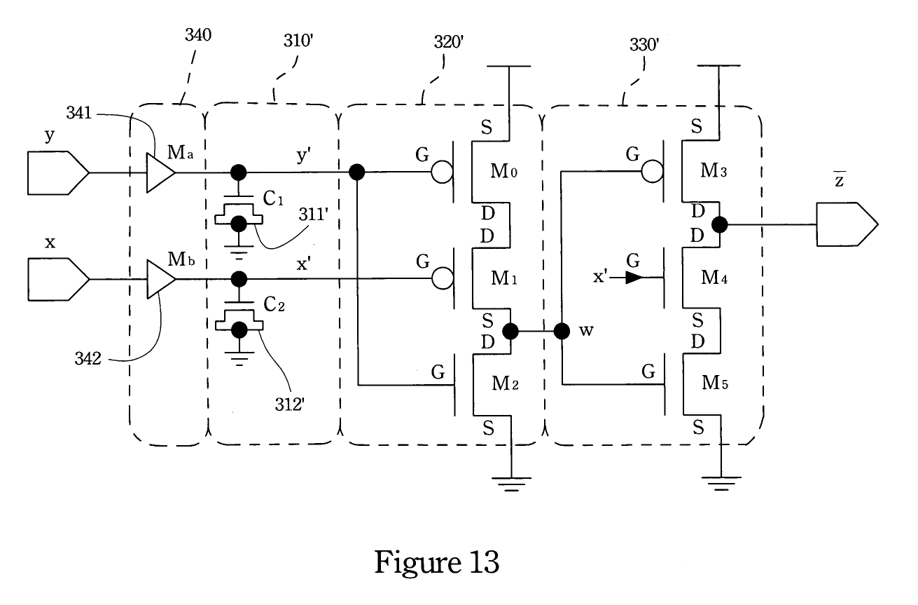

Refer to FIG. 13. FIG. 13 is another circuit diagram which illustrates a second embodiment of the DTHT module in FIG. 7. The difference between FIG. 8 and FIG. 13 is that the first capacitor 311 and the second capacitor 312 of the first embodiment are changed into the first MOS capacitor 311′ and the second MOS capacitor 312′ of the first logic unit 310′. A fourth logic unit 340 is also added between the paths of the input signal y and the input signal x and the first logic unit 310′. The fourth logic unit 340 includes a first logic gate 341 (Mₐ) cascaded in the input signal y and a second logic gate 342 (M_{b}) cascaded in the input signal x, and both the first logic gate 341 (Mₐ) and the second logic gate 342 (M_{b}) are buffers. The circuit schemes of the second logic unit 320′ and the third logic unit 330′ are the same as the circuit schemes of the first embodiment in FIG. 8.

The second embodiment of the present invention can make the integrated circuit of the phase detector practice, and further produces a more imperceptible delay period difference. In addition, the first logic gate 341 (Mₐ) and the second logic gate 342 (M_{b}) can reduce signal strength tolerance of the input signal y and the input signal x.

Although the present invention has been described in considerable detail with reference to certain preferred embodiments thereof, other embodiments are possible. Therefore, their spirit and scope of the appended claims should no be limited to the description of the preferred embodiments container herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A differential-type high-speed phase detector, comprising:
a first DTHT module including a first input for receiving a first signal, a second input for receiving a second signal, a first logic unit, a second logic unit, a third logic unit and an output, and the first logic unit including a first capacitor and a second capacitor; and
a second DTHT module including a first input for receiving the first signal, a second input for receiving the second signal and an output;
wherein the first input of the first DTHT module connects with the second input of the second DTHT module, the second input of the first DTHT module connects with the first input of the second DTHT module.

2. The differential-type high-speed phase detector of claim 1, wherein the second DTHT module and the first DTHT module are identical.

3. The differential-type high-speed phase detector of claim 1, wherein the first capacitor connects with the first input of the first DTHT module, and the second capacitor connects with the second input of the first DTHT module.

4. The differential-type high-speed phase detector of claim 3, further comprising a first input new signal transformed by the first signal entered from the first input and passed through the first capacitor, and a second input new signal transformed by the second signal entered from the second input and passed through the second capacitor.

5. The differential-type high-speed phase detector of claim 4, wherein a capacitance value of the first capacitor is bigger than a capacitance value of the second capacitor.

6. The differential-type high-speed phase detector of claim 1, wherein the second logic unit includes a first switch element, a second switch element and a third switch element, and these three switch elements are cascaded with each other.

7. The differential-type high-speed phase detector of claim 6, wherein the first switch element is a P-type metal-oxide-semiconductor (PMOS) with a gate (G) connecting with the first input of the first DTHT module.

8. The differential-type high-speed phase detector of claim 6, wherein the second switch element is a P-type metal-oxide-semiconductor (PMOS) with a gate (G) connecting with the second input of the first DTHT module.

9. The differential-type high-speed phase detector of claim 6, wherein the third switch element is a N-type metal-oxide-semiconductor (NMOS) with a gate (G) connecting with the first input of the first DTHT module.

10. The differential-type high-speed phase detector of claim 6, wherein the second switch element and the third switch element of the second logic unit respectively have a drain (D) connected to each other to form an output of the second logic unit.

11. The differential-type high-speed phase detector of claim 10, wherein an input of the third logic unit connects with the output of the second logic unit.

12. The differential-type high-speed phase detector of claim 11, wherein the third logic unit includes a first switch element, a second switch element and a third switch element, and these three switch elements are cascaded with each other.

13. The differential-type high-speed phase detector of claim 12, wherein the first switch element of the third logic unit is a P-type metal-oxide-semiconductor (PMOS) with a gate (G) connecting with the output of the second logic unit.

14. The differential-type high-speed phase detector of claim 12, wherein the second switch element of the third logic unit is a N-type metal-oxide-semiconductor (NMOS) with a gate (G) for receiving a second input new signal.

15. The differential-type high-speed phase detector of claim 12, wherein the third switch element of the third logic unit is a N-type metal-oxide-semiconductor (NMOS) with a gate (G) connecting with the output of the second logic unit.

16. The differential-type high-speed phase detector of claim 12, wherein the first switch element and the second switch element of the third logic unit respectively have a drain (D) connected to each other to form an output of the first DTHT module.

17. The differential-type high-speed phase detector of claim 5, wherein the first capacitor and the second capacitor are fixed capacitors.

18. The differential-type high-speed phase detector of claim 5, wherein the first capacitor and the second capacitor are metal-oxide-semiconductor (MOS) capacitors.

19. The differential-type high-speed phase detector of claim 2, wherein each of the first DTHT module and the second DTHT module further includes a fourth logic unit cascaded with the first signal, the second signal and the first logic unit.

20. The differential-type high-speed phase detector of claim 19, wherein the fourth logic unit includes a first logic gate and a second logic gate.

21. The differential-type high-speed phase detector of claim 20, wherein the first logic gate and the second logic gate are buffers.
